(19) United States
(12) Patent Application Publication
(10) Pub. No.: US 2025/0248144 A1
(43) Pub. Date: Jul. 31, 2025

(54) INFRARED SENSOR

(71) Applicant: National Tsing Hua University, Hsinchu City (TW)

(72) Inventors: Hsueh-Shih CHEN, Hsinchu City (TW); Pei-Cheng HUANG, Hsinchu City (TW); Chen-Te LIN, Hsinchu City (TW)

(21) Appl. No.: 18/733,190

(22) Filed: Jun. 4, 2024

(30) Foreign Application Priority Data
Jan. 30, 2024 (TW) 113103483

(51) Int. Cl. H01L 27/146; H04N 5/33

(52) U.S. Cl. CPC H10F 39/193; H04N 5/33

(57) ABSTRACT

An infrared sensor includes a substrate, a first electrode, a light-sensing unit, and a second electrode. The substrate is infrared-transmissible. The first electrode is disposed on a surface of the substrate and is infrared-transmissible. The light-sensing unit is disposed on a surface of the first electrode opposite to the substrate, is capable of absorbing and sensing infrared light, and includes a zinc oxide (ZnO)-based layer, a first lead sulfide (PbS)-based modification layer, and a second PbS-based modification layer that are sequentially stacked from the surface of the first electrode. The first PbS-based modification layer includes halide ion-modified PbS, and the second PbS-based modification layer includes thiol-modified PbS. In addition, the second electrode is disposed on a surface of the light-sensing unit opposite to the substrate, and is capable of forming a current flow path by cooperating with the light-sensing unit and the first electrode.

### CROSS-REFERENCE TO RELATED APPLICATION

This application claims priority to Taiwanese Invention Patent Application No. 113103483, filed on Jan. 30, 2024, the entire disclosure of which is incorporated by reference herein.

### FIELD

The disclosure relates to a light sensor, and more particularly to an infrared sensor.

### BACKGROUND

Silicon is a major element adopted to serve as a sensing material of a conventional image sensor. However, silicon shows insufficient light conversion efficiency for long-wavelength light (>1100 nm) and inadequate low-light sensing capability. In order to alleviate the abovementioned problems, lead sulfide quantum dots (PbS-QDs) are utilized as a light sensing material of a sensing component for sensing long-wavelength light. Although use of PbS-QDs as the light sensing material improves light conversion efficiency for long-wavelength light as well as provides good responsibility (R) to the sensing component, such sensing component is generally made to be a planar thin film transistor, where two electrodes thereof have a greater distance with respect to a plane of the planar thin film transistor, causing the sensing component to require a higher driving voltage for operation and resulting in response time delay. Consequently, PbS-QDs have to confront with the limitations in application to the light sensing field.

In order to alleviate the aforesaid shortcomings of the planar thin film transistor, a vertical light sensing element is developed. However, in the vertical light sensing element, a large number of vacancies usually exist on a carrier transfer interface between a surface of PbS-QDs and those of other materials different from PbS, which affects the overall conductivity of the vertical light sensing element, and thus limits the application of PbS-QDs in the vertical light sensing element.

### SUMMARY

Therefore, an object of the disclosure is to provide an infrared sensor that can alleviate at least one of the drawbacks of the prior art.

According to the disclosure, the infrared sensor includes a substrate, a first electrode, a light-sensing unit, and a second electrode.

The substrate is infrared-transmissible. The first electrode is disposed on a surface of the substrate and is infrared-transmissible. The light-sensing unit is disposed on a surface of the first electrode opposite to the substrate, is capable of absorbing and sensing infrared light, and includes a zinc oxide (ZnO)-based layer, a first lead sulfide (PbS)-based modification layer, and a second PbS-based modification layer that are sequentially stacked from the surface of the first electrode. The first PbS-based modification layer includes halide ion-modified PbS, and the second PbS-based modification layer includes thiol-modified PbS. In addition, the second electrode is disposed on a surface of the light-sensing unit opposite to the substrate, and is capable of forming a current flow path by cooperating with the light-sensing unit and the first electrode.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic view illustrating an infrared sensor according an embodiment of the disclosure.

FIG. 2 is a schematic view illustrating an implantation of a second electrode of the infrared sensor according to the embodiment of the disclosure.

FIG. 3A is a plot illustrating variation of current density versus bias voltage of different sensing elements, each of which has a modified zinc oxide (ZnO) layer that includes certain ethanolamine-modified ZnO nanoparticles modified by ethanolamine in a distinct concentration.

FIG. 3B is a partially enlarged view of the plot of FIG. 3A.

FIG. 4A is a scanning electron microscope (SEM) image showing a cross-sectional structure of a sensing unit.

FIG. 4B is a plot illustrating current densities in dark current (I_{d}) and photocurrent (Iₚₕ) measured in each sensing unit under different bias voltages.

FIG. 4C is a plot illustrating responsivities of each sensing unit under different bias voltages.

FIG. 4D is a plot illustrating detectivities of each sensing unit under different bias voltages.

FIG. 5A are SEM images illustrating surface morphologies of a lead sulfide (PbS)-based modification layer (indicated as “PbS—I layer”) in different scales.

FIG. 5B are SEM images illustrating surface morphologies of another PbS-based modification layer (indicated as “PbS-EDT layer”) in different scales.

FIG. 5C are SEM images illustrating surface morphologies of a stacked structure including both a PbS—I layer and a PbS-EDT layer (indicated as “PbS-I/PbS-EDT layer”) in different scales.

FIGS. 6A to 6D are plots respectively illustrating dark currents (I_{d}), photocurrents (Iₚₕ), responsivities (R_{λ}), and detectivities (D) of an infrared sensor of Example under different bias voltages.

FIGS. 7A to 7D are plots respectively illustrating dark currents (I_{d}), photocurrents (Iₚₕ), responsivities (R_{λ}), and detectivities (D) of an infrared sensor of Comparative Example 2 under different bias voltages.

FIGS. 8A to 8C are plots respectively illustrating photocurrents (Iₚₕ), responsivities (R_{λ}), and detectivities (D) of the infrared sensor of Example under different bias voltages and different irradiation powers.

FIGS. 9A to 9C are plots respectively illustrating photocurrents (Iₚₕ), responsivities (R_{λ}), and detectivities (D) of an infrared sensor of Comparative Example 1 under different bias voltages and different irradiation powers.

FIGS. 10A to 10D are plots respectively illustrating dark currents (I_{d}), photocurrents (Iₚₕ), responsivities (R_{λ}), and detectivities (D) of the infrared sensor of the Example under different bias voltages and a certain irradiation power (i.e., Pₒᵤₜ=310 μW/cm²).

FIGS. 11A to 11D are plots respectively illustrating dark currents (I_{d}), photocurrents (Iₚₕ), responsivities (R_{λ}), and detectivities (D) of an infrared sensor of Comparative Example 3 under different bias voltages and a certain irradiation power (i.e., Pₒᵤₜ=310 μW/cm²).

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

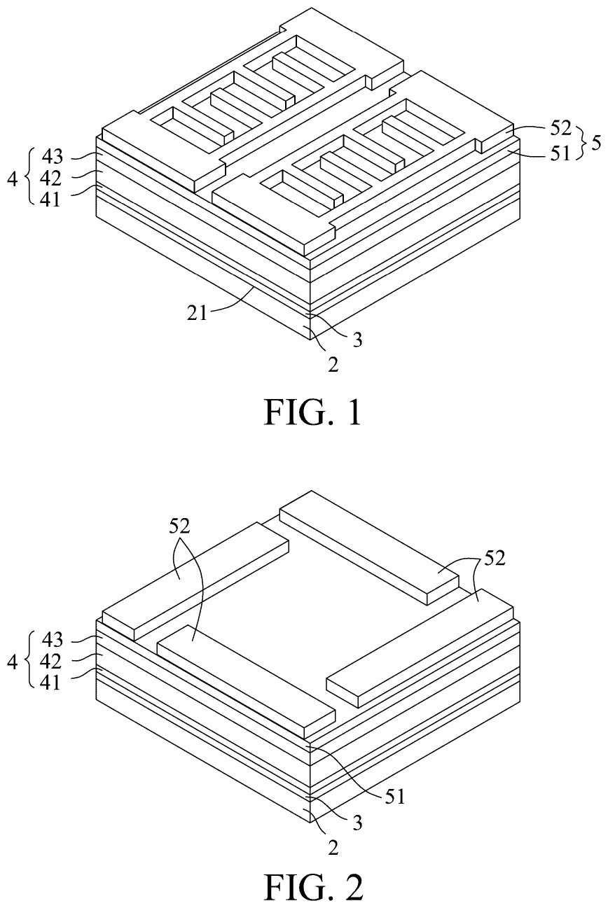

Referring to FIG. 1, an embodiment of an infrared sensor according to the disclosure includes a substrate 2, a first electrode 3, a light-sensing unit 4, and a second electrode 5.

The substrate 2 is infrared-transmissible, and may be made of glass, sapphire, polyethylene terephthalate, or polyimide.

The first electrode 3 is disposed on a surface 21 of the substrate 2, and is mainly made of a transparent conductive oxide material that is infrared-transmissible. The transparent conductive oxide material may be a conductive metal oxide selected from the group consisting of indium tin oxide (ITO), indium zinc oxide (IZO), aluminum zinc oxide (AZO), antimony tin oxide (ATO) and so on, and may be further doped with conductive dopants, such as carbon nanotubes, silver nanowires or the like.

The light-sensing unit 4 is disposed on a surface of the first electrode 3 opposite to the substrate 2, is capable of absorbing and sensing infrared light, and includes a zinc oxide (ZnO)-based layer 41, a first lead sulfide (PbS)-based modification layer 42, and a second PbS-based modification layer 43 that are sequentially stacked from the surface of the first electrode 3. In certain embodiments, the ZnO-based layer 41 includes at least one first self-assembled film formed by self-assembly of first nanoparticles (first quantum dots (QDs)), the first PbS-based modification layer 42 includes at least one second self-assembled film formed by self-assembly of second nanoparticles (second QDs), and the second PbS-based modification layer 43 includes at least one third self-assembled film formed by self-assembly of third nanoparticles (third QDs).

In certain embodiments, the first nanoparticles, the second nanoparticles, and the third nanoparticles are self-assembled in a sphere packing, and have a particle size ranging from 1 nm to 30 nm.

In certain embodiments, the light-sensing unit 4 has a thickness ranging from 50 nm to 500 nm, and the first PbS-based modification layer 42 has a thickness greater than a thickness of the second PbS-based modification layer 43.

Specifically, the ZnO-based layer 41 includes amine-modified ZnO nanoparticles and ZnO nanoparticles. The amine-modified ZnO nanoparticles are obtained by mixing ZnO nanoparticles with an amine, followed by a reaction thereof. The amine-modified ZnO nanoparticles and the ZnO nanoparticles have a particle size ranging from 1 nm to 30 nm. That is to say, the at least one first self-assembled film of the ZnO-based layer 41 is formed by self-assembly of the amine-modified ZnO nanoparticles and the ZnO nanoparticles (all together serving as the first nanoparticles or the first QDs) in a sphere packing, and the ZnO-based layer 41 has an average surface roughness (Rq) of not greater than 1.5 nm.

In other embodiments, the ZnO-based layer 41 has a thickness ranging from 1 nm to 30 nm.

In certain embodiments, the amine in the amine-modified ZnO nanoparticles is a primary amine with a substituent, which is a linear alkyl group having a carbon number of not greater than 8. By controlling the carbon number of the substituent (i.e., length of the linear alkyl group), not only can surface properties of the ZnO nanoparticles be modified, but also change in conductivity of the ZnO nanoparticles that are to be modified by the amine can be minimized, thereby maintaining conductivity of the ZnO-based layer 41.

In some embodiments, the amine is selected from the group consisting of ethanolamine (EA), ethylenediamine (EDA), n-butylamine, polyethyleneimine (PEI), and combinations thereof.

The first PbS-based modification layer 42 includes PbS nanoparticles and halide ion-modified PbS nanoparticles (PbSₓX₁₋ₓ, where X represents halide ions, and 0<x<1). The halide ion-modified PbS nanoparticles are obtained by mixing PbS nanoparticles with a lead halide (PbX₂), followed by a reaction thereof. In other words, the at least one second self-assembled film of the first PbS-based modification layer 42 is formed by self-assembly of the PbS nanoparticles and/or the halide ion-modified PbS nanoparticles (all together serving as the second nanoparticles or the second QDs) in a sphere packing.

In some embodiments, the PbS nanoparticles and the halide ion-modified PbS nanoparticles have a particle size ranging from 1 nm to 30 nm.

In still some embodiments, the halide ions in the halide ion-modified PbS nanoparticles are selected from the group consisting of chloride ions, bromide ions, and iodide ions.

The second PbS-based modification layer 43 includes PbS nanoparticles and thiol-modified PbS nanoparticles (PbS_{y}M_{1-y}, where M represents thiol ions, and 0<y<1). The thiol-modified PbS nanoparticles are obtained by mixing PbS nanoparticles with a thiol, followed by a reaction thereof. To be specific, the at least one third self-assembled film of the second PbS-based modification layer 43 is formed by self-assembly of the PbS nanoparticles and/or the thiol-modified PbS nanoparticles (all together serving as the third nanoparticles or the third QDs) in a sphere packing.

In certain embodiments, the thiol is 1,2-ethanedithiol (EDT).

Specifically, the light-sensing unit 4 is prepared by, initially, coating a first mixture on the first electrode 3 using spin coating or spray coating, followed by removing a first solvent in the first mixture, thereby obtaining the ZnO-based layer 41. The first mixture includes the first solvent, ZnO nanoparticles, and the amine. The amine is used to conduct surface modification of the ZnO nanoparticles, and the ZnO nanoparticles are present in an amount ranging from 1 wt % to 10 wt % based on 100 wt % of the first mixture. In some embodiments, the ZnO nanoparticles have a particle size ranging from 5 nm to 8 nm, and are present in an amount ranging from 3 wt % to 6 wt % based on 100 wt % of the first mixture.

Subsequently, a second mixture is coated on the ZnO-based layer 41 using spin coating or spray coating, followed by removing a second solvent in the second mixture, thus forming the first PbS-based modification layer 42. The second mixture includes the second solvent, PbS nanoparticles, and the lead halide (in a supersaturated concentration) that is used to conduct surface modification of the PbS nanoparticles. Finally, a third mixture is coated on the first PbS-based modification layer 42 using spin coating and spray coating, followed by removing a third solvent in the third mixture, thus forming the second PbS-based modification layer 43. The third mixture includes the third solvent, PbS nanoparticles, and the thiol that is used to conduct surface modification of the PbS nanoparticles. After stacking the second PbS-based modification layer 43 on the first PbS-based modification layer 42, the light-sensing unit 4 is obtained.

It can be seen from the above description that a desired number of the first self-assembled film(s) in the ZnO-based layer 41, a desired number of the second self-assembled film(s) in the first PbS-based modification layer 42, or a desired number of the third self-assembled film(s) in the second PbS-based modification layer 43 can be obtained simply by controlling the number of time(s) of coating (the first mixture, the second mixture or the third mixture) and drying (removing the first solvent, the second solvent, or the third solvent).

The first solvent of the first mixture is selected from the group consisting of water, methanol, ethanol, isopropanol, and combinations thereof, and the amine is present in an amount ranging from 0.01 vol % to 1 vol % based on 100 vol % of the first mixture. In certain embodiments, the amine is present in an amount ranging from 0.05 vol % to 0.5 vol % based on 100 vol % of the first mixture. In addition, in order to prevent a situation where an excessive amount of the amine is present in the first mixture, which may generate an excessive amount of the amine-modified ZnO nanoparticles and affect the flatness and smoothness of the thus formed ZnO-based layer 41, in other embodiments, the amine is present in an amount ranging from 0.05 vol % to 0.2 vol % based on 100 vol % of the first mixture. In still other embodiments, the amine is present in an amount ranging from 0.05 vol % to 0.1 vol % based on 100 vol % of the first mixture.

Each of the second solvent in the second mixture and the third solvent in the third mixture may be selected from the group consisting of toluene, N, N-dimethylmethanamide (DMF), and acetonitrile (ACN). In addition, the PbS nanoparticles in each of the second mixture and the third mixture have a particle size ranging from 3 nm to 10 nm. The PbS nanoparticles in the second mixture are present in an amount ranging from 4 wt % to 10 wt % based on 100 wt % of the second mixture, and the PbS nanoparticles in the third mixture are present in an amount ranging from 4 wt % to 10 wt % based on 100 wt % of the third mixture.

The second electrode 5 is disposed on a surface of the light-sensing unit 4 opposite to the substrate 2, and is capable of forming a current flow path by cooperating with the light-sensing unit 4 and the first electrode 3.

To be more specific, the second electrode 5 may be formed on the surface of the light-sensing unit 4 by evaporation or coating, and may include a first metal film 51 and a second metal film 52. The first metal film 51 is in direct contact with the surface of the light-sensing unit 4, is capable of forming an ohmic contact with the light-sensing unit 4, and hence has good electron conductivity. The second metal film 52 is formed on a surface of the first metal film 51 opposite to the light-sensing unit 4, and has good conductivity, and/or is not prone to oxidation so as to provide protection to the first metal film 51. In brief, the first metal film 51 and the second metal film 52 are sequentially stacked from the surface of the light-sensing unit 4 opposite to the substrate 2. The second metal film 52 may be formed entirely on the surface of the first metal film 51, or may be formed on part of the surface of the first metal film 51 (in this case, the second metal film 52 may be also referred to as a patterned metal film). For instance, the second metal film 52 may be formed to partially expose the surface of the first metal film 51, and may include two parts each of which has two sections that are arranged to be interdigitated with each other as shown in FIG. 1. In other embodiments, the second metal film 52 may include several parts each having a rectangular shape, and the several parts may be arranged on the surface of the first metal film 51 in a manner as shown in FIG. 2. That is to say, the structure of the second metal film 52 is not particularly limited. For example, in this embodiment, the first metal film 51 is made of molybdenum oxide (MoO₃) (in this case, the first metal film 51 is also referred to as a conductive metal oxide film), and the second metal film 52, which is made of aluminum (Al), is formed on part of the surface of the first metal film 51 by evaporation.

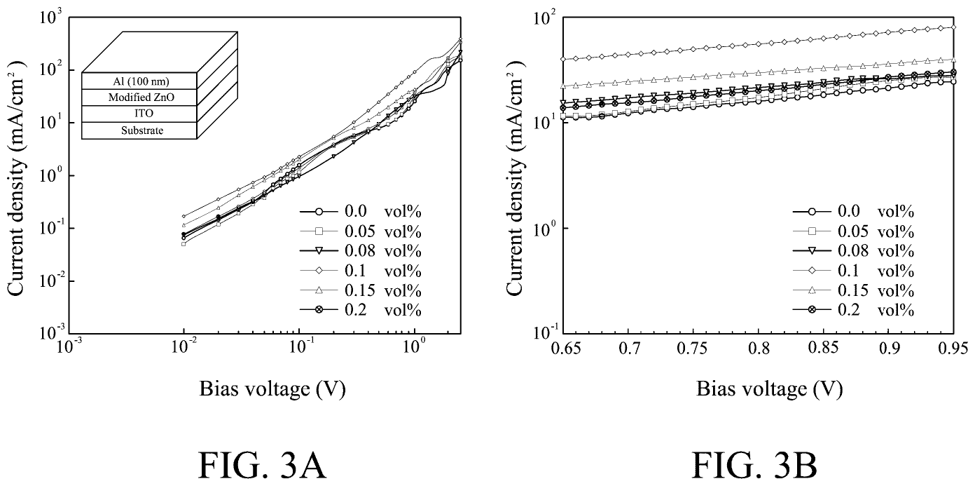

FIG. 3A shows electrical measurement results of different sensing elements, each of which includes a substrate, an ITO layer, a modified ZnO layer and an aluminum (Al) layer. The concentrations of ethanolamine-modified ZnO (EA-ZnO) nanoparticles in the modified ZnO layers of the sensing elements range from 0 vol % to 0.2 vol %. FIG. 3B is a partially enlarged view of the plot shown in FIG. 3A.

As shown in FIGS. 3A and 3B, by adding ethanolamine to modify ZnO nanoparticles, surface defects on the ZnO nanoparticles can be passivated and surface roughness of the modified ZnO layer can be reduced, so as to improve the mobility of carriers, thereby obtaining a higher current density. Moreover, when the ethanolamine used for modifying ZnO nanoparticles is present in an amount of 0.1 vol %, the sensing element shows the highest current density (i.e., the highest carrier mobility). In addition, as shown in FIGS. 3A and 3B, when the ethanolamine used is present in an amount greater than 0.1 vol %, the current density, as well as the carrier mobility decreases, which is presumably due to a decrease in flatness of the sensing element. These results confirm that by performing surface modification on the ZnO nanoparticles with an appropriate amount of amine, carrier mobility of the sensing element can indeed be improved.

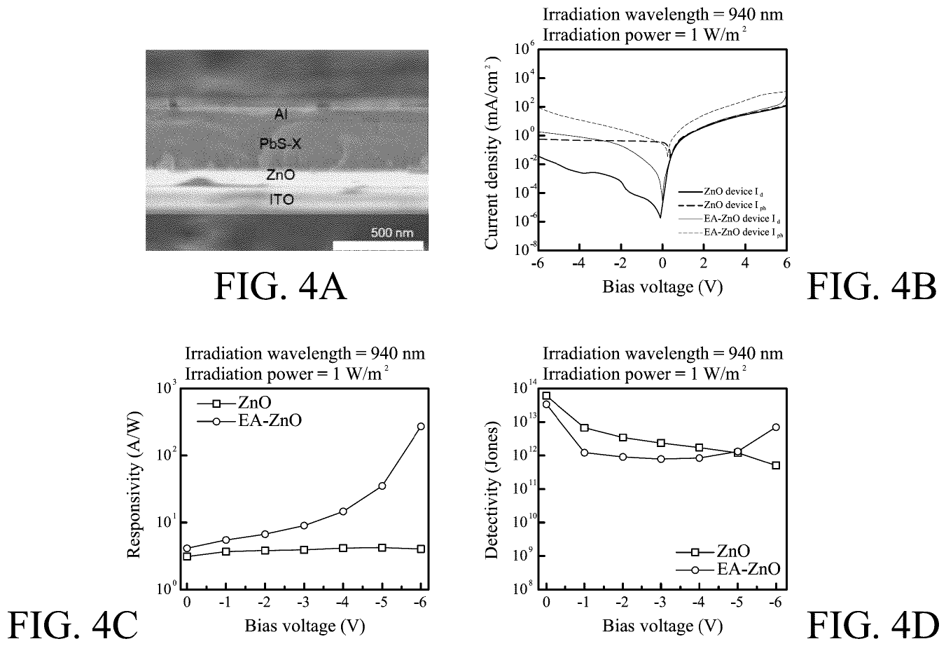

FIGS. 4A to 4D show electrical measurement results of two sensing units, one of which (hereinafter indicated as “ZnO device”) has a light sensing unit containing halogen-modified PbS (PbS-X) and an electron transmission layer containing ZnO (i.e., non-modified ZnO), and another one of which (hereinafter indicated as “EA-ZnO device”) has a light sensing unit containing PbS-X and an electron transmission layer containing EA-ZnO. FIG. 4A is a scanning electron microscope (SEM) image showing a cross-sectional structure of the sensing unit (i.e., the ZnO device or the EA-ZnO device). FIG. 4B shows the current densities in dark current (I_{d}) and photocurrent (Iₚₕ) measured in each of the ZnO device and the EA-ZnO device. FIG. 4C shows the responsivities of each of the ZnO device and the EA-ZnO device under different bias voltages, and FIG. 4D shows the detectivities of each of the ZnO device and the EA-ZnO device under different bias voltages.

Referring to FIG. 4C, the responsivity at an irradiation wavelength of 940 nm (R_{λ}) of the ZnO device or the EA-ZnO device is calculated according to the following Equation (1):

$${R}_{λ} = {I}_{p h} / {P}_{out} \qquad ( 1 )$$

where R_{λ} is a responsivity at an irradiation wavelength of 940 nm;
   Iₚₕ is a photocurrent; and
   Pₒᵤₜ is an irradiation power.

Referring to FIG. 4D, the detectivity (D) of the ZnO device or the EA-ZnO device are calculated according to the following Equation (2):

$$D = {R}_{λ} \sqrt{S / 2 {qI}_{d}} \qquad ( 2 )$$

where D is a detectivity;
   R_{λ} is a responsivity at an irradiation wavelength of 940 nm;
   S is a sensing area;
   q is a charge amount; and
   I_{d} is a dark current.

The results in FIGS. 4B to 4D show that, by using the electron transmission layer containing EA-ZnO, surface defects can be passivated and carrier recombination can be inhibited. Therefore, electron mobility is increased, and hence photocurrent of the EA-ZnO device is greatly enhanced, thereby effectively improving the responsivity of the EA-ZnO device. Furthermore, because the photocurrent (Iₚₕ) of the EA-ZnO device is significantly increased under a high in bias voltage (i.e., −4V to −6V) (see FIG. 4B), improved responsivity and detectivity can be observed under such high bias voltage (see FIGS. 4C and 4D).

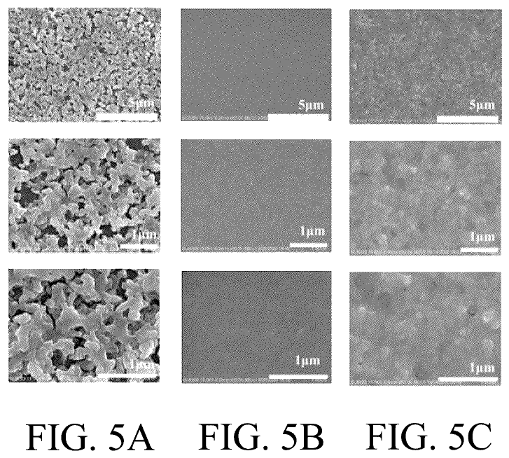

FIG. 5A are SEM images showing a PbS-based modification layer (can be deemed equivalent to the first PbS-based modification layer 42 of the disclosure; hereinafter indicated as “PbS—I layer”) which is coated on a surface of a glass substrate and which includes iodide ion-modified PbS nanoparticles. FIG. 5B are SEM images showing another PbS-based modification layer (can be deemed equivalent to the second PbS-based modification layer 43 of the disclosure; hereinafter indicated as “PbS-EDT layer”) which is coated on a surface of a glass substrate and which includes 1,2-ethylenedithiol (EDT)-modified PbS nanoparticles. FIG. 5C are SEM images showing a stacked structure including both a PbS—I layer and a PbS-EDT layer which are sequentially coated on a surface of a glass substrate.

As shown in FIGS. 5A and 5B, the surface flatness of the PbS—I layer is not good, but the PbS-EDT layer that includes the EDT-modified PbS nanoparticles show an improved surface flatness. Accordingly, as shown in FIG. 5C, by utilizing the stacked structure including the PbS—I layer and the PbS-EDT layer, the PbS-EDT layer (equivalent to the second PbS-based modification layer 43 of the disclosure) can be used to greatly reduce surface roughness of the PbS—I layer (equivalent to the first PbS-based modification layer 42 of the disclosure), so that a contact interface between the light-sensing unit 4 and the second electrode 5 can be planarized, thereby achieving an improved charge transfer effect.

The following Example and Comparative Examples 1 to 3 are used to describe the electrical properties of the infrared sensor prepared in the Example and infrared sensors respectively prepared in the Comparative Examples 1 to 3.

Solutions used in each of the Example and the Comparative Examples 1 to 3 are described as follows.

The ZnO solution contains a solvent (isopropanol) and ZnO nanoparticles (particle size: 5.8 nm; present in an amount of 4 wt % based on 100 wt % of the ZnO solution).

The modified-ZnO solution (serving as the abovementioned first mixture) contains a solvent (isopropanol; serving as the abovementioned first solvent), ZnO nanoparticles (particles size: 5.8 nm; present in an amount of 4 wt % based on 100 wt % of the modified-ZnO solution), and ethanolamine (EA; serving as the abovementioned amine, present in an amount of 0.1 vol % based on 100 vol % of the modified-ZnO solution).

The PbS solution contains a solvent (dimethylformamide (DMF)) and PbS nanoparticles (particle size: 3.4 nm; present in an amount of 5 wt % based on 100 wt % of the PbS solution).

The first modified-PbS solution (serving as the abovementioned second mixture) contains a solvent (DMF; serving as the abovementioned second solvent), PbS nanoparticles (particle size: 3.4 nm; present in an amount of 5 wt % based on 100 wt % of the first modified-PbS solution), and lead (II) iodide (PbI₂; serving as the abovementioned lead halide; present in an amount of 9 wt % based on 100 wt % of the first modified-PbS solution).

The second modified-PbS solution (serving as the abovementioned third mixture) contains a solvent (acetonitrile (ACN); serving as the abovementioned third solvent), PbS nanoparticles (particle size: 3.4 nm; present in an amount of 5 wt % based on 100 wt % of the second modified-PbS solution), and 1,2-ethylenedithil (EDT; serving as the abovementioned thiol; present in an amount of 0.02 vol % based on 100 vol % of the second modified-PbS solution).

### EXAMPLE

First, the modified-ZnO solution was spin-coated on a surface of an ITO layer (serving as the first electrode 3) stacked on a glass substrate (serving as the substrate 2), so that the modified-ZnO solution was formed into a ZnO self-assembly coating, followed by drying the ZnO self-assembly coating, that is, to remove the solvent (i.e., isopropanol) of the modified-ZnO solution, thereby obtaining a ZnO-based layer (serving as the abovementioned ZnO-based layer 41) that has a thickness of 25 nm and is indicated as “ZnO-EA layer”.

Subsequently, the first modified-PbS solution was spin-coated on a surface of the ZnO-based layer, so that the first modified-PbS solution was formed into a first PbS self-assembly coating, followed by drying the first PbS self-assembly coating at 60° C., that is, to remove the solvent (i.e., DMF) of the first modified-PbS solution, thereby obtaining a first PbS-based modification layer (serving as the abovementioned first PbS-based modification layer 42) that has a thickness of 200 nm and is indicated as “PbS—I layer”.

Thereafter, the second modified-PbS solution was spin-coated on a surface of the first PbS-based modification layer, so that the second modified-PbS solution was formed into a second PbS self-assembly coating, followed by drying the second PbS self-assembly coating at 60° C., that is, to remove the solvent (i.e., ACN) of the second modified-PbS solution, thereby obtaining a second PbS-based modification layer (serving as the abovementioned second PbS-based modification layer 43) that has a thickness of 144 nm and is indicated as “PbS-EDT layer”.

Finally, a first metal layer (serving as the aforesaid first metal film 51) made of molybdenum oxide (MoO₃) was formed on a surface of the second PbS-based modification layer using an evaporation method, and a second metal layer (serving as the aforesaid second metal film 52) made of aluminum (Al) was formed on part of a surface of the first metal layer, thereby obtaining the infrared sensor of the Example.

In brief, the infrared sensor of the Example included, from bottom to top, the glass substrate, the ITO layer, the ZnO-EA layer, the PbS—I layer, the PbS-EDT layer, the first metal layer made of MoO₃, and the second metal layer made of Al.

### Comparative Example 1

The procedures and conditions for making the infrared sensor of the Comparative Example 1 were generally similar to those of the infrared sensor of the Example 1, except that use of the first modified-PbS solution for making the PbS—I layer and use of the second modified-PbS solution for making the PbS-EDT layer were entirely replaced by use of the PbS solution for making a PbS layer. That is, instead of forming the PbS—I layer and the PbS-EDT layer, merely the PbS layer was formed in the Comparative Example 1.

Briefly, the infrared sensor of the Comparative Example 1 included, from bottom to top, a glass substrate, an ITO layer, a ZnO-EA layer, the PbS layer, a first metal layer made of MoO₃, and a second metal layer made of Al.

### Comparative Example 2

The procedures and conditions for making the infrared sensor of the Comparative Example 2 were generally similar to those of the infrared sensor of the Example, except that use of the modified-ZnO solution for making the ZnO-EA layer was replaced by use of the ZnO solution for making a ZnO layer.

Briefly, the infrared sensor of the Comparative Example 2 included, from bottom to top, a glass substrate, an ITO layer, the ZnO layer, a PbS—I layer, a PbS-EDT layer, a first metal layer made of MoO₃, and a second metal layer made of Al.

### Comparative Example 3

The procedures and conditions for making the infrared sensor of the Comparative Example 3 were generally similar to those of the infrared sensor of the Example, except that use of the first modified-PbS solution for making the PbS—I layer was replaced by use of the PbS solution for making a PbS layer.

In brief, the infrared sensor of the Comparative Example 3 included, from bottom to top, a glass substrate, an ITO layer, a ZnO-EA layer, the PbS layer, a PbS-EDT layer, a first metal layer made of MoO₃, and a second metal layer made of Al.

Each of the infrared sensor of the Example and the infrared sensors of the Comparative Examples 1 to 3 was subjected to measurements of electrical properties.

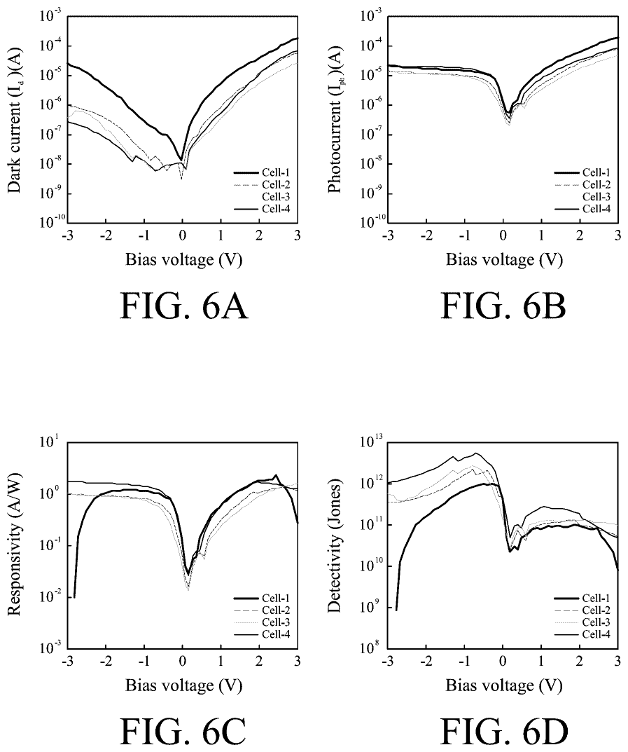

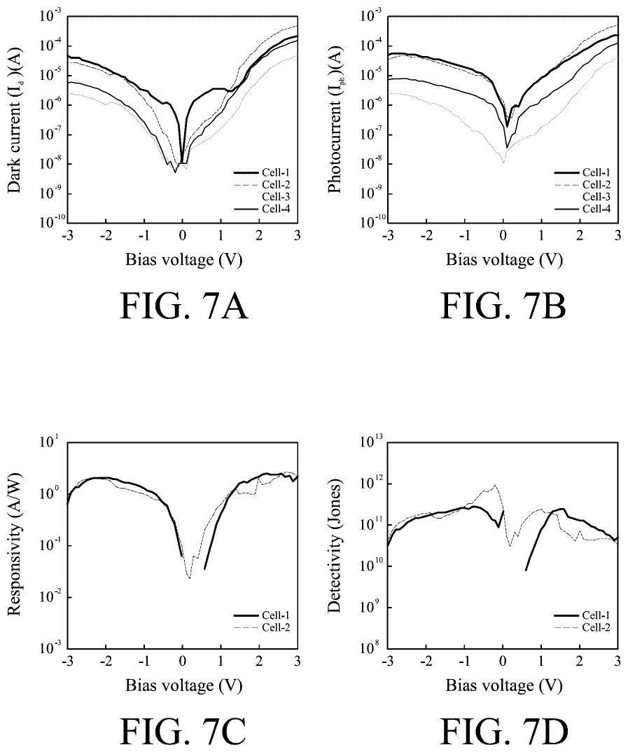

FIGS. 6A to 6D illustrate measurements of the electrical properties of the infrared sensor of the Example, and FIGS. 7A to 7D illustrate measurements of the electrical properties of the infrared sensor of the Comparative Example 2. The electrical properties were measured under an irradiation wavelength of 940 nm and an irradiation power (Pₒᵤₜ) of 310 μW/cm². In addition, the results of the aforesaid measurements were summarized in Table 1 below. FIGS. 6A to 6D respectively show the dark currents (I_{d}), photocurrents (Iₚₕ), responsivities (R_{λ}), and detectivities (D) of the infrared sensor of the Example; and FIGS. 7A to 7D respectively show the dark currents (I_{d}), photocurrents (Iₚₕ), responsivities (R_{λ}), and detectivities (D) of the infrared sensor of the Comparative Example 2. Moreover, the labels “Cell-1” to “Cell-4” shown in each of the FIG. 6A to FIG. 6D and FIG. 7A to FIG. 7D represent results obtained at different times in a course of repeated experiments.

TABLE 1

| | Example | Comparative Example 2 |
|---|---|---|
| Dark current (I_{d}, A) | 10⁻⁸-10⁻⁷ | 10⁻⁷-10⁻⁵ |
| Photocurrent (Iₚₕ, A) | 10⁻⁵-10⁻⁴ | 10⁻⁵-10⁻⁴ |
| Responsivity (R_{λ}, A/W) | 10⁰-10¹ | 10⁰-10¹ |
| Detectivity (D, Jones) | −10¹² | −10¹¹ |

The responsivity (R_{λ}) and detectivity (D) of each of the Example and the Comparative Example 2 were respectively calculated using the Equations (1) and (2) mentioned above.

It can be inferred from the results in Table 1 that, in the infrared sensor of the Example, since the ZnO nanoparticles in the ZnO-based layer (ZnO-EA layer) are subjected to surface modification, the interface compatibility between the first electrode 3 (i.e., the ITO layer) and the light-sensing unit 4 (i.e., the ZnO-EA layer, the PbS—I layer, and the PbS-EDT layer) is effectively improved, thereby improving electron transmission efficiency. Compared to the infrared sensor of the Comparative Example 2, the infrared sensor according to the disclosure, i.e., the infrared sensor of the Example, achieves a better responsivity and detectivity.

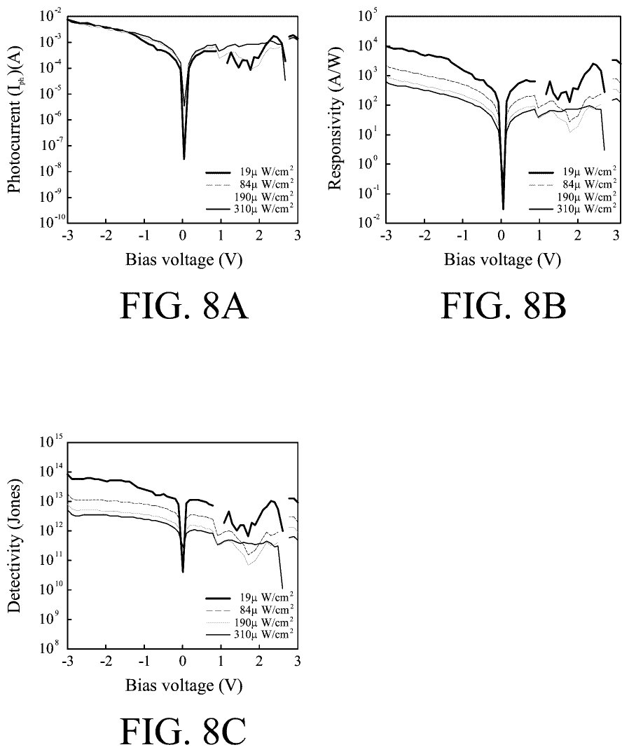

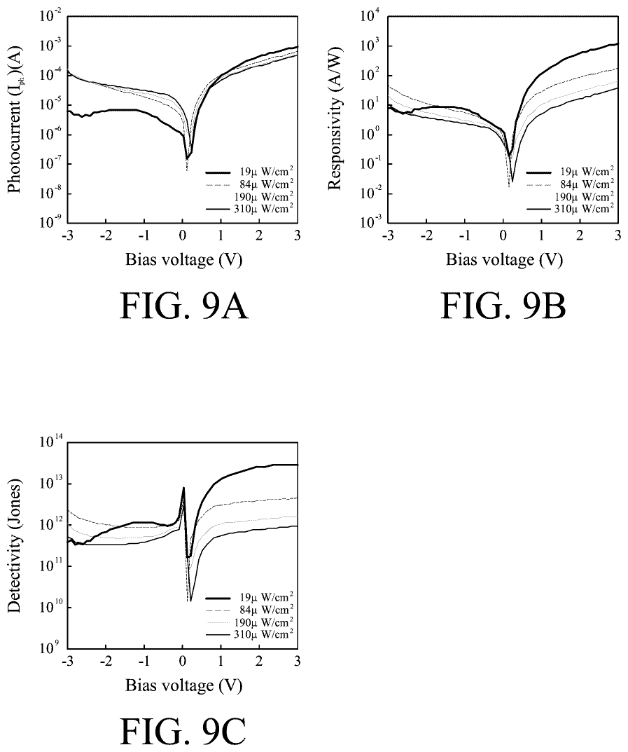

FIGS. 8A to 8C illustrate measurements of the electrical properties of the infrared sensor of the Example, and FIGS. 9A to 9C illustrate measurements of the electrical properties of the infrared sensor of the Comparative Example 1. The electrical properties were measured, under an irradiation wavelength of 940 nm and irradiation powers (Pₒᵤₜ) of 19 μW/cm², 84 μW/cm², 190 μW/cm², and 310 μW/cm², respectively. In addition, the results of the aforesaid measurements were summarized in Table 2 below. FIGS. 8A to 8C respectively show the photocurrents (Iₚₕ), responsivities (R_{λ}), and detectivities (D) of the infrared sensor of the Example (EX); and FIGS. 9A to 9C respectively show the photocurrents (Iₚₕ), responsivities (R_{λ}), and detectivities (D) of the infrared sensor of the Comparative Example 1 (CE1). The values measured at a bias voltage of −1 V presented in Table 2 were based on the measurements shown in FIGS. 8A to 8C and FIGS. 9A to 9C.

TABLE 2

| | | Responsivity | |
|---|---|---|---|
| Irradiation power | Photocurrent (Iₚₕ, A) | (R_{λ}, A/W) | Detectivity (D, Jones) |
| (μW/cm²) | (CE1/EX) | (CE1/EX) | (CE1/EX) |
| 19 | 6.6 × 10⁻⁶/1.1 × 10⁻³ | 7.4/1383 | 1.2 × 10¹²/2.5 × 10¹³ |
| 84 | 1.6 × 10⁻⁴/1.6 × 10⁻³ | 5.6/455 | 9.0 × 10¹¹/8.2 × 10¹² |
| 190 | 1.7 × 10⁻⁴/1.6 × 10⁻³ | 3.3/202 | 5.4 × 10¹¹/3.7 × 10¹² |
| 310 | 1.5 × 10⁻⁴/1.8 × 10⁻³ | 2.5/142 | 4.1 × 10¹¹/2.6 × 10¹² |

As shown in FIGS. 8A to 8C and FIGS. 9A to 9C and Table 2, the infrared sensor of the Example has better optoelectronic properties as compared to the infrared sensor of the Comparative Example 1. It can be inferred from the results in Table 1 that the lower the irradiation power applied to the infrared sensor of the Example, the better the responsivity and detectivity of the infrared sensor is.

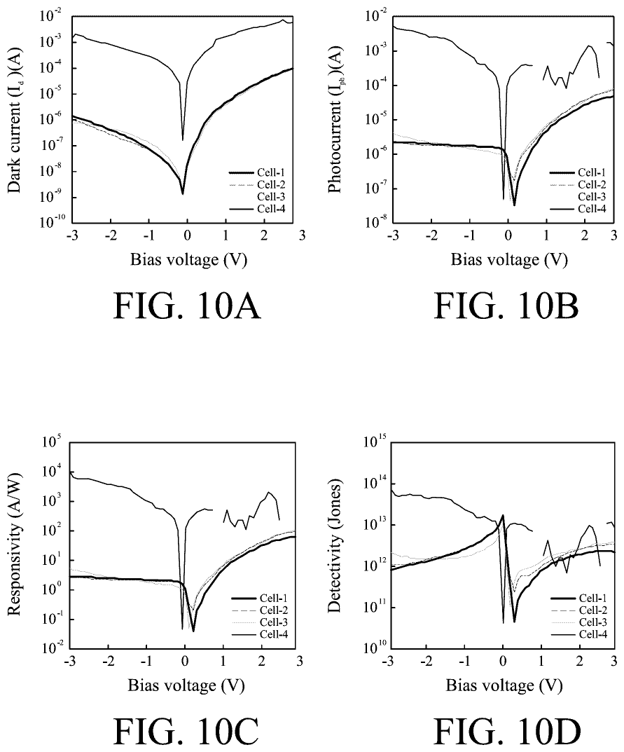

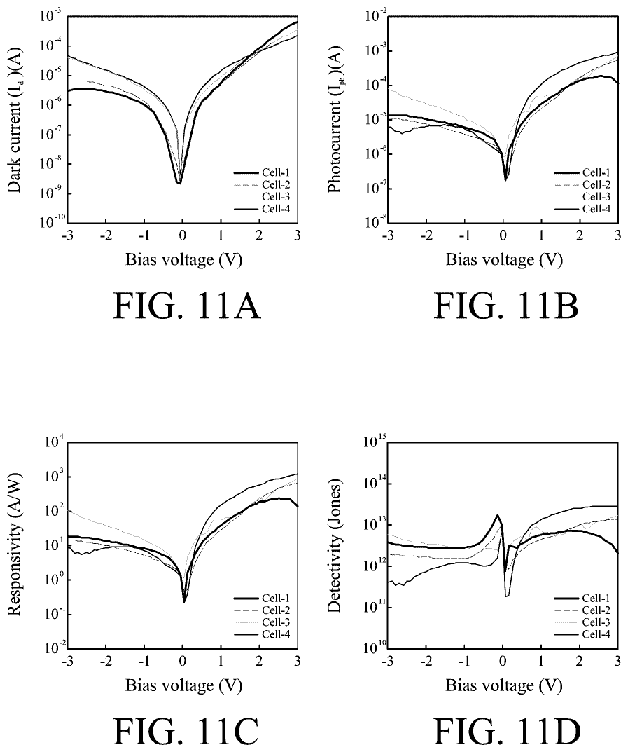

FIGS. 10A to 10D illustrate measurements of the electrical properties of the infrared sensor of the Example, and FIGS. 11A to 11D illustrate measurements of the electrical properties of the infrared sensor of the Comparative Example 3. The electrical properties were measured, under an irradiation wavelength of 940 nm and an irradiation power (Pₒᵤₜ) of 310 ρW/cm². In addition, the results of the aforesaid measurements were summarized in Table 3 below. FIGS. 10A to 10D respectively show the dark currents (I_{d}), photocurrents (Iₚₕ), responsivities (R_{λ}), and detectivities (D) of the infrared sensor of the Example; and FIGS. 11A to 11D respectively show the dark currents (I_{d}), photocurrents (Iₚₕ), responsivities (R_{λ}), and detectivities (D) of the infrared sensor of the Comparative Example 3.

TABLE 3

| | Example | Comparative Example 3 |
|---|---|---|
| Dark current (I_{d}, A) | 10⁻⁶-10⁻³ | 10⁻⁵-10⁻⁴ |
| Phorocurrent (Iₚₕ, A) | 10⁻⁶-10⁻² | 10⁻⁵-10⁻⁴ |
| Responsivity (R_{λ}, A/W) | −10⁴ | −10³ |
| Detectivity (D, Jones) | −10¹⁴ | −10¹³ |

The results presented in FIGS. 10 and 11 as well as Table 3 show that the infrared sensor according to the disclosure has better responsivity and detectivity as compared to the infrared sensor of the Comparative Example 3.

In sum, by providing modified ZnO nanoparticles (i.e., some of the ZnO nanoparticles that have undergone surface modification due to use of the amine (i.e., ethanolamine)) in the ZnO-based layer 41 of the light-sensing unit 4 that is in direct contact with the first electrode 3, and by utilization of the amine to fill oxygen vacancies in ZnO lattices, surface defects on the ZnO nanoparticles can be passivated, and occurrence of carrier recombination is limited, thereby enhancing carrier mobility of the ZnO-based layer. In addition, because ZnO has a greater hydrophilicity and PbS has a greater lipophilicity, the contact interface between ZnO and PbS would not have a good compatibility, thus affecting charge transfer efficiency. Therefore, by using the modified ZnO nanoparticles, lipophilic property of a surface of ZnO can be improved, so as to improve compatibility between ZnO and PbS, thereby enhancing the charge transfer efficiency. Moreover, by using different functional groups to modify PbS (functioning as a light absorbing material), the first PbS-based modification layer 42, which is in direct contact with the ZnO-based layer 41 and includes halogen-modified PbS nanoparticles (i.e., the PbS nanoparticles modified by the PbI₂), is formed with improved electron injection efficiency, and the second PbS-based modification layer 43, which includes thiol-modified PbS nanoparticles (i.e., the PbS nanoparticles modified by the 1,2-ethylenedithil), is formed to protect the first PbS-based modification layer 42 and to planarize roughness thereof, thus resulting in a contact interface between the light-sensing unit 4 and the second electrode 5 having higher flatness, thereby improving electron transmission efficiency and hence, elevating the overall responsivity and detectivity of the infrared sensor according to the disclosure.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is (are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. An infrared sensor, comprising:
a substrate being infrared-transmissible;
a first electrode disposed on a surface of said substrate and being infrared-transmissible;
a light-sensing unit disposed on a surface of said first electrode opposite to said substrate, being capable of absorbing and sensing infrared light, and including a zinc oxide (ZnO)-based layer, a first lead sulfide (PbS)-based modification layer, and a second PbS-based modification layer that are sequentially stacked from said surface of said first electrode, said first PbS-based modification layer including halide ion-modified PbS, said second PbS-based modification layer including thiol-modified PbS; and
a second electrode disposed on a surface of said light-sensing unit opposite to said substrate, and being capable of forming a current flow path by cooperating with said light-sensing unit and said first electrode.

2. The infrared sensor as claimed in claim 1, wherein halide ions in said halide ion-modified PbS are selected from the group consisting of chloride ions, bromide ions, and iodide ions, and wherein a thiol in said thiol-modified PbS is 1,2-ethanedithiol.

3. The infrared sensor as claimed in claim 1, wherein said ZnO-based layer includes a first self-assembled film formed by self-assembly of first nanoparticles, said first PbS-based modification layer includes a second self-assembled film formed by self-assembly of second nanoparticles, and said second PbS-based modification layer includes a third self-assembled film formed by self-assembly of third nanoparticles.

4. The infrared sensor as claimed in claim 3, wherein said first nanoparticles are self-assembled in a sphere packing, and having a particle size ranging from 1 nm to 30 nm.

5. The infrared sensor as claimed in claim 1, wherein said ZnO-based layer includes amine-modified ZnO nanoparticles.

6. The infrared sensor as claimed in claim 5, wherein an amine in said amine-modified ZnO nanoparticles is a primary amine with a substituent which is a linear alkyl group having a carbon number of not greater than 8.

7. The infrared sensor as claimed in claim 6, wherein said ZnO-based layer is formed by coating a mixture on said first electrode, followed by removing a solvent in said mixture, said mixture including said solvent, ZnO nanoparticles and said amine, said amine being present in an amount ranging from 0.05 vol % to 0.5 vol % based on 100% of said mixture.

8. The infrared sensor as claimed in claim 7, wherein said solvent is selected from the group consisting of water, methanol, ethanol, isopropanol, and combinations thereof, and said ZnO-based layer has an average surface roughness (Rq) of not greater than 1.5 nm.

9. The infrared sensor as claimed in claim 1, wherein said light-sensing unit has a thickness ranging from 50 nm to 500 nm, and said first PbS-based modification layer has a thickness greater than a thickness of said second PbS-based modification layer.

10. The infrared sensor as claimed in claim 1, wherein said substrate is made of glass, and said first electrode is made of a transparent conductive oxide material, said second electrode including a conductive metal oxide film and a patterned metal film that are sequentially stacked from said surface of said light-sensing unit opposite to said substrate.
